(19) United States
(12) Patent Application Publication
(10) Pub. No.: US 2012/0196410 A1
(43) Pub. Date: Aug. 2, 2012

(54) METHOD FOR FABRICATING FIN FIELD EFFECT TRANSISTOR

(75) Inventors: Teng-Chun TSAI, Tainan City (TW); Chun-Yuan Wu, Yunlin County (TW); Chih-Chien Liu, Taipei City (TW); Chin-Fu Lin, Tainan City (TW); Chin-Cheng Chien, Tainan County (TW)

(73) Assignee: UNITED MICROELECTRONICS CORP, HSINCHU (TW)

(21) Appl. No.: 13/017,534

(22) Filed: Jan. 31, 2011

(51) Int. Cl. H01L 21/336

(52) U.S. Cl. 438/151; 257/E21.409

(57) ABSTRACT

A method for fabricating a fin-FET, wherein the method comprises several steps as follows: A substrate is first provided, and a silicon fin is then formed in the substrate. Next a dielectric layer is formed on the silicon fin and the substrate. A poly silicon layer is subsequently formed on the dielectric layer, and the poly silicon layer is then planarized. Subsequently, a poly silicon gate is formed and a portion of the silicon fin is exposed by patterning the planarized poly silicon layer. A source and a drain are separately formed on two opposite sides of the exposed silicon fin adjacent to the poly silicon gate.

### FIELD OF THE INVENTION

The present invention relates to a method for fabricating a semiconductor device, more particularly to a method for fabricating a fin field effect transistor (fin-FET).

### BACKGROUND OF THE INVENTION

FIG. 1A illustrates a schematic diagram of a fin field effect transistor 100 in accordance with prior art. Referring to FIG. 1A, A typical fin-FET, such as the fin-FET 100, is formed on a Silicon-on-Insulator (SOI) substrate 102 comprising a silicon base 102a, an insulator layer 102b and an epitaxial silicon layer 102c. Since the source 104a and drain 104b of the fin-FET 100 are separately defined on a three dimensional fin 104, and the gate 106 of the fin-FET 100 straddles on the three sidewalls of the fin 104, thus a plurality of gate areas which is referred as a multiple gate structure are configured.

In comparison with a conventional planar transistor which has a single gate structure, the leakage current in the multiple gate structure is significantly lower than that in the single gate structure. Accordingly current new generation semiconductor process, such as 28 nm technology node and beyond, prefers to adopt the fin-FET approach in order to solve the problems of current leakage and short channel effects due to the minimization of semiconductor critical dimension.

However, the conventional fin-FET 100 still has drawbacks. FIG. 1B illustrates a schematic cross section of the fin-FET 100 shown on FIG. 1A. Since a typical fin-FET (such a the fin-FET 100) may comprise a plurality of three dimensional fins 104, and each of the three dimensional fins 104 on which the source 104a and drain 104b is defined protrudes from the surface of the SOI substrate 102, thus when a poly silicon layer 110 used to form the gate 106 is deposited on these three dimensional fins 104, the topography of the silicon layer 110 may undulate (shown as FIG. 1B), and the production yield may be inversely affected. These inverse effects may be getting worse particularly for to the semiconductor process with the critical dimension less than 28 nm.

Therefore it is necessary to provide an improved method for fabricating a fin-FET that can relieve the undulating topography of the gate, so as to improve the production yield.

### SUMMARY OF THE INVENTION

One aspect of the present invention is to provide a method for fabricating a fin-FET, wherein the method comprises several steps as follows: A substrate is first provided, and a silicon fin is then formed in the substrate. Next a dielectric layer is formed on the silicon fin and the substrate. A poly silicon layer is subsequently formed on the dielectric layer, and the poly silicon layer is then planarized. Subsequently a poly silicon gate is formed and a portion of the silicon fin is exposed by patterning the planarized poly silicon layer. A source and a drain are separately formed on two opposite sides of the exposed silicon fin adjacent to the poly silicon gate.

In some embodiments of the present invention, the substrate is a SOI substrate having a silicon base, an insulator layer and an epitaxial silicon layer, and the steps for forming the silicon fin comprise a step of patterning the epitaxial silicon layer of the SOI substrate to form a three dimensional silicon fin and expose a portion of the insulator layer.

In some embodiments of the present invention, the dielectric layer comprises a high dielectric constant layer. In some embodiments of the present invention, the method further comprises a step of forming a gate material layer on the high dielectric constant layer and before the poly silicon layer is formed.

In some embodiments of the present invention, the formation of the source and the drain comprises several steps as follows: An optional light doped drain (LDD) implantation process is first conducted to form a first LDD region and a second LDD region on two opposite sides of the silicon fin adjacent to the poly silicon gate. A spacer is then formed on the sidewalls of the poly silicon gate to surround the poly silicon gate. Subsequently, the first LDD region and the second LDD region are subjected to an ion implantation process or a plasma doping process.

In some embodiments of the present invention, further comprises forming a silicide layer on the poly silicon gate, the source and the drain after the source and the drain are defined.

In some embodiments of the present invention, after the source and the drain are defined, further comprises removing the poly silicon gate, and forming a metal gate. In some embodiments of the present invention, removing the poly silicon gate comprises steps as follows: An internal dielectric layer is formed on the ploy silicon gate and the substrate. A planarization process is then conducted on the internal dielectric layer to expose the poly silicon gate. Subsequently, the poly silicon gate is removed to form an opening in the internal dielectric layer, whereby a portion of the dielectric layer can be exposed from the opening. In some embodiments of the present invention, before the internal dielectric layer is formed, a contact etch stop layer (CESL) may be formed on the ploy silicon gate and the substrate. In some embodiments of the present invention, the formation of the metal gate comprises steps as follows: A metal layer is formed on the internal dielectric layer and the exposed dielectric layer to fulfill the opening. A polishing process is then conducted on the metal layer and stopped on the internal dielectric layer to remove a portion of the metal layer and a portion of the internal dielectric layer.

In some embodiments of the present invention, the planarization of the poly silicon layer comprises chemical mechanical polishing (CMP). In one preferred embodiment of the present invention, an advanced patterning film (APF) is formed on the poly silicon layer before the CMP is conducted.

In some embodiments of the present invention, a hard mask may be formed on the planarized poly silicon layer before the planarized poly silicon layer is patterned. In one preferred embodiment, the hard mask is made of silicon nitride or silicon oxide.

According to aforementioned embodiments of the present invention, a method for fabricating a fin-FET is provided, wherein the source and the drain of the fin-FET are separately formed on a three dimensional fin, and the gate straddles on the fin between the source and drain. By way of conducting a planarization step on a poly silicon layer that is used to form a gate structure during the process for fabricating the fin-FET, the undulating topography of the gate structure can be made more even in order to comply with the process requirement of new generation semiconductor, whereby the production yield can be increased.

In order to make the aforementioned and other objects, features and advantages of the present invention comprehensible, preferred embodiments accompanied with figures are described in detail below.

### BRIEF DESCRIPTION OF THE DRAWINGS

The above objects and advantages of the present invention will become more readily apparent to those ordinarily skilled in the art after reviewing the following detailed description and accompanying drawings, in which:

FIG. 1A illustrates a schematic diagram of a fin-FET in accordance with prior art.

FIG. 1B illustrates a schematic cross section of another fin-FET in accordance with prior art.

FIGS. 2A to 2J illustrate schematic diagrams of a process for fabricating a fin-FET in accordance with an embodiment of the present invention.

FIG. 2D′ illustrates a cross section prior the poly silicon layer is planarized in accordance with another embodiment of the present invention.

FIG. 2F′ illustrates a simplified diagram indicating the structure after the poly silicon layer is planarized in accordance with the preferred embodiment.

FIGS. 3A to 3O illustrate schematic diagrams of a process for fabricating a fin-FET in accordance with further another embodiment of the present invention.

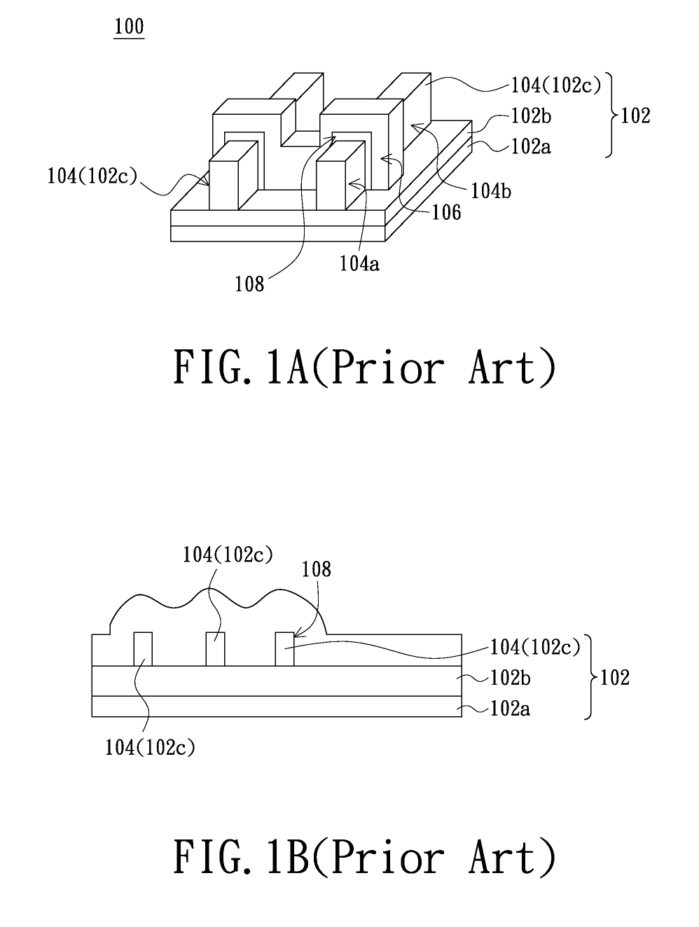

### DETAILED DESCRIPTION OF PREFERRED EMBODIMENTS

Detail descriptions of several embodiments eligible to exemplify the features of making and using the present invention are disclosed as follows. It must be appreciated that the following embodiments are just exemplary, but not used to limit the scope of the present invention. Wherever possible, the same reference numbers are used in the drawings and the description to refer to the same or like parts.

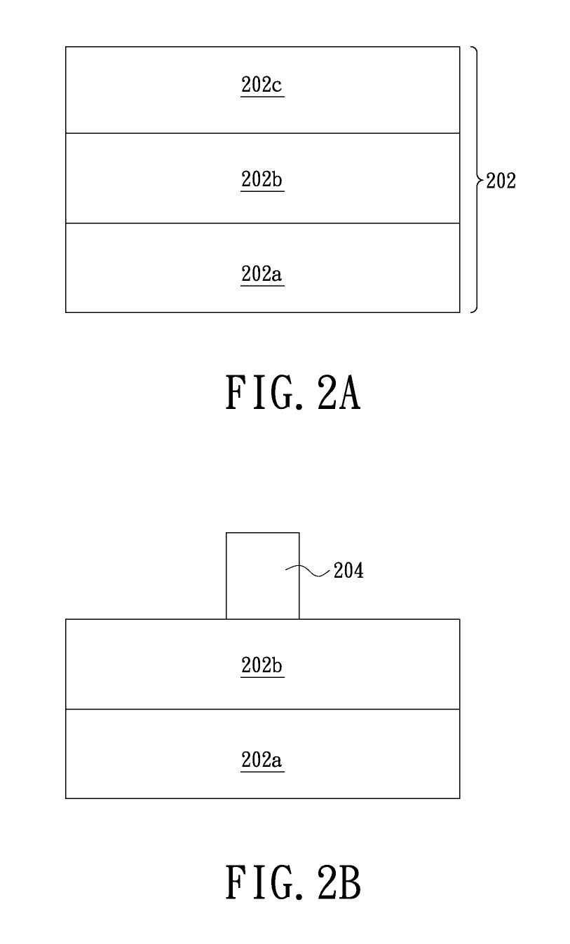

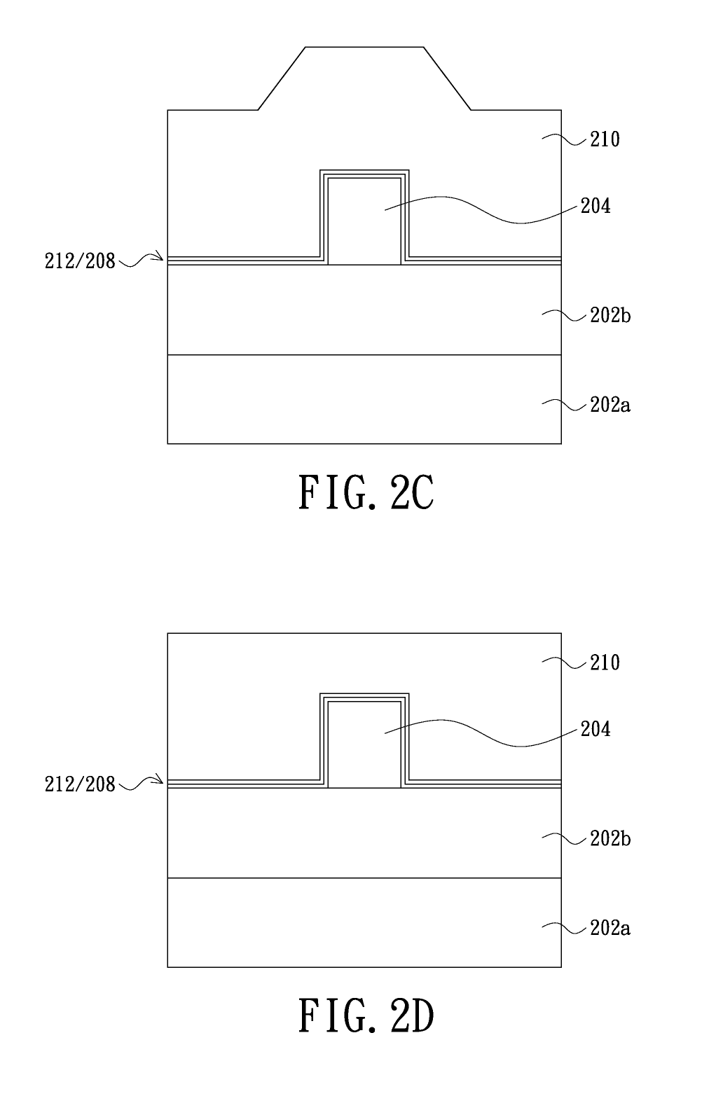

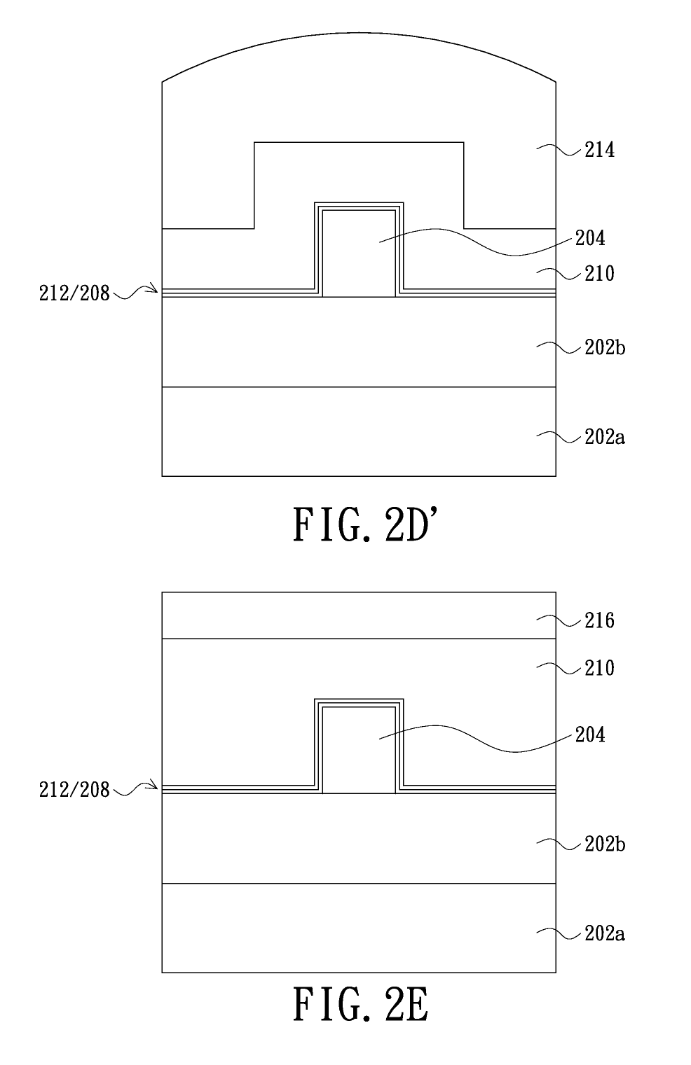

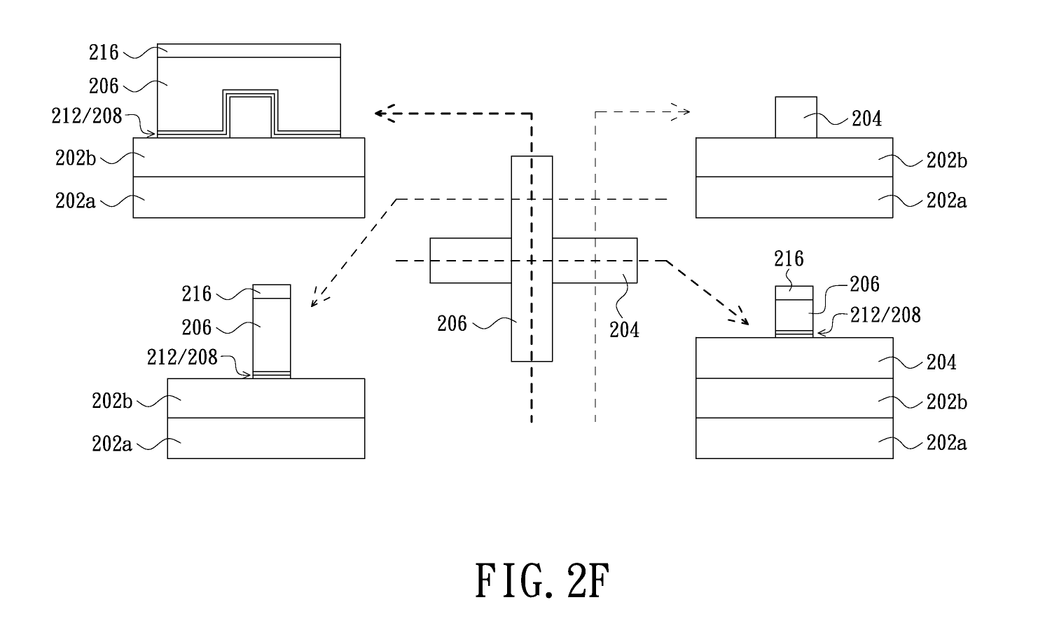

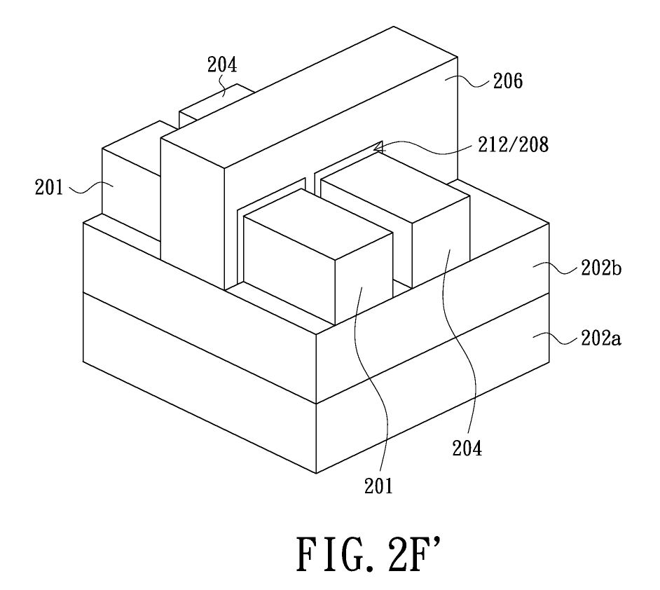

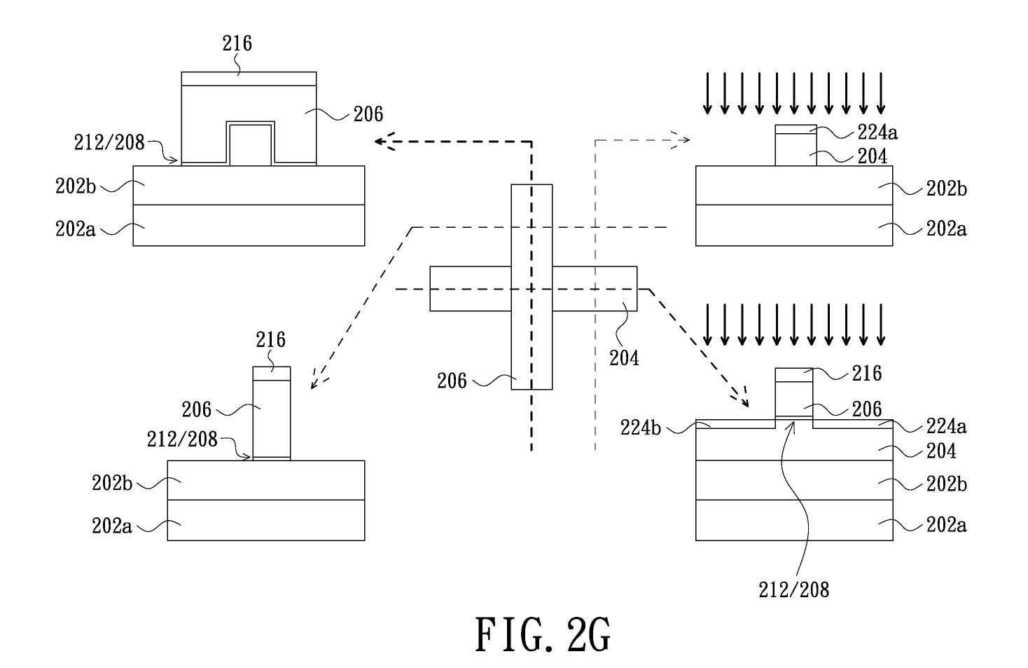

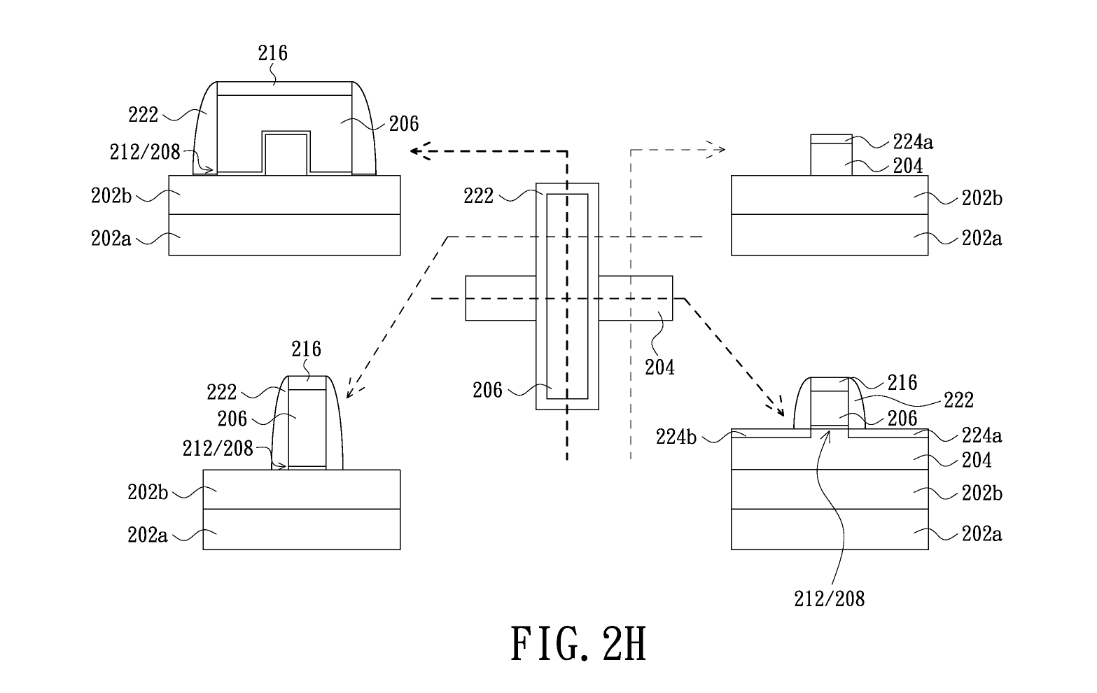

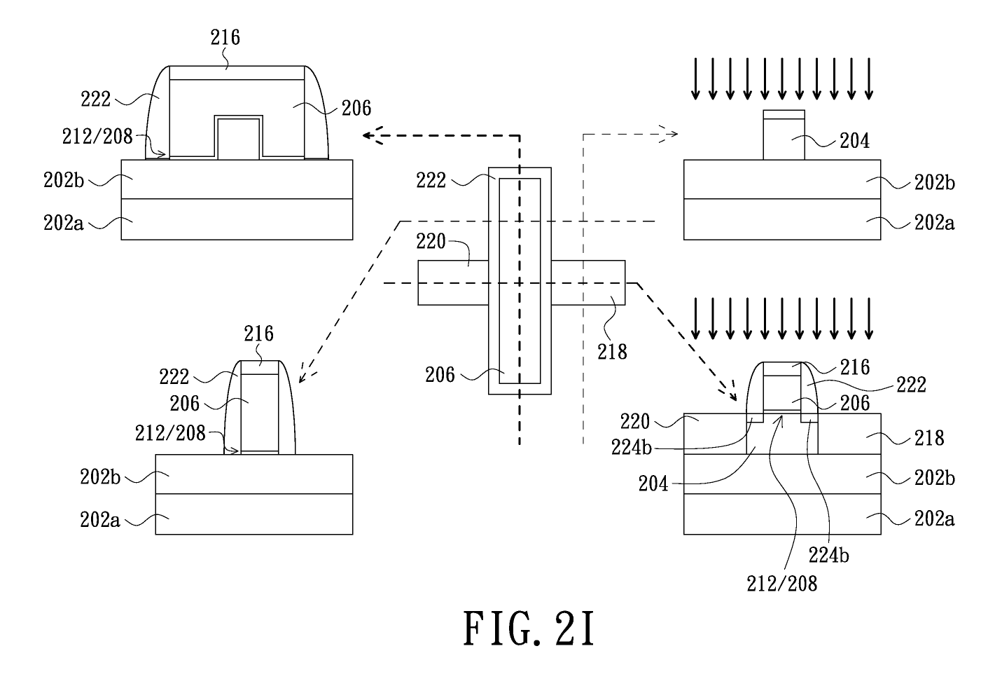

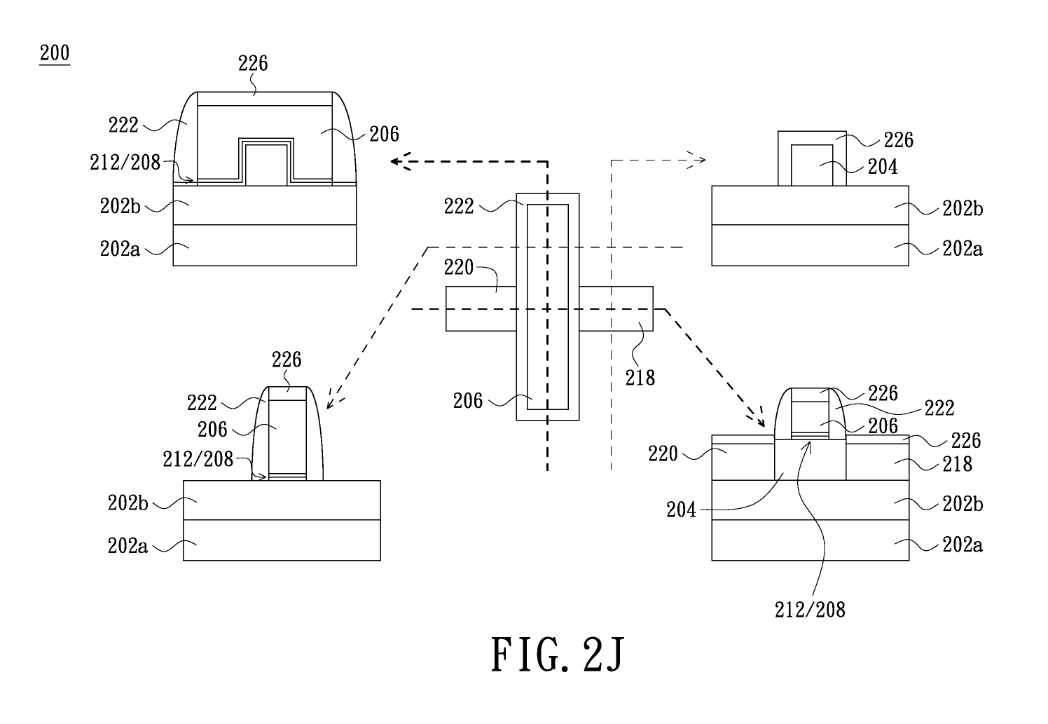

The object of the present invention is to provide an improve method for fabricating a fin-FET. FIGS. 2A to 2J illustrate schematic diagrams of a process for fabricating a fin-FET 200 in accordance with an embodiment of the present invention.

In the present embodiment the method for fabricating the fin-FET 200 comprises several steps as follows: A substrate 202 is first provided. As shown in FIG. 2A, the substrate 202 is a SOI substrate having a silicon base 202a, an insulator layer 202b and an epitaxial silicon layer 202c.

A silicon fin 204 is then formed in the substrate 202. In the present embodiment, the silicon fin 204 is formed by a conventional lithography and etching process, whereby the epitaxial silicon layer 202c is patterned to form the three dimensional silicon fin 204 in the SOI substrate and a portion of the insulator layer 202b is exposed. The three dimensional silicon fin 204 is a bulk structure shapes as a rectangular solid, a cylinder or a polyhedron. In the preset embodiment, the three dimensional silicon fin 204 is a rectangular solid (as shown in FIG. 2B).

Next, a dielectric layer 208 is formed blanket over the silicon fin 204 and the exposed insulator layer 202b. Subsequently, a poly silicon layer 210 is formed further blanket over the dielectric layer 208. In the present embodiment, the dielectric layer 208 is a high dielectric constant layer, consists of silicon nitride, silicon oxide oxynitride or the arbitrary combination thereof. In some embodiments, a gate material layer 212 may be formed on dielectric layer 208 (as shown in FIG. 2C), before the poly silicon layer 210 is formed on the dielectric layer 208.

Since the three dimensional silicon fin 204 is a rectangular solid protruding from the surface of the SOI 204, thus the SOI 204 has an undulating surface topography, and when the dielectric layer 208, the gate material layer 212 and the poly silicon layer 210 are blanketed onto the three dimensional silicon fin 204, the surface of the poly silicon layer 210 may undulates in comply with the undulating topography of the SOI 204, and the production yield may be inversely affected. To avoid this inverse effects, a planarization step, such as a CMP step, is conducted to remove a portion of the poly silicon layer 210 (as shown in FIG. 2D), so as to render the undulating topography of the poly silicon layer 210 relief.

FIG. 2D′ illustrates a cross section prior the poly silicon layer 210 is planarized in accordance with another embodiment of the present invention. In the embodiment of the present invention, an APF 214 is further formed on the poly silicon layer 210 prior the planarization step is conducted.

After the planarization step is implemented, the planarized poly silicon layer 210 is patterned to define a poly silicon gate 206 (as shown in FIG. 2F). In the present embodiment, the poly silicon gate 206 is defined by a conventional lithography and etching process. Before the poly silicon layer 210 is patterned, preferably a hard mask consists of silicon nitride or silicon oxide may be formed on the planarized poly silicon layer 210 (as shown in FIG. 2E).

FIG. 2F′ illustrates a simplified diagram indicating the structure after the poly silicon layer 210 is planarized in accordance with the preferred embodiment. Since the undulating topography of the poly silicon layer 210 is relieved by the planarization step, the poly silicon gate 206 defined from the planarized poly silicon layer 210 has a flat roof. In other words, the top surface of poly silicon gate 206 do not undulated in accordance with the undulating topography of the SOI substrate 202, even if the poly silicon gate 206 straddles several three dimensional silicon fins 204. It should be noted that FIG. 2F′ is just simplified for the purpose of more clearly describing the features of the present invention, thus some elements are omitted. The omitted elements are illustrated and described on the other paragraph of the detail description and the pertinent drawings.

After the poly silicon gate 206 is formed, a source 218 and a drain 220 are separately formed on two opposite sides of the silicon fin 204 adjacent to the ploy silicon gate 206. In the present embodiment, the formation of the source 218 and the drain 220 comprises the following steps: A LDD implantation process is first conducted to form a first LDD region 224a and a second LDD region 224b on the two opposite sides of the silicon fin 204 adjacent to the poly silicon gate 206, whereby the poly silicon gate 206 can straddle over the silicon fin 204 between the first LDD region 224a and the second LDD region 224b (as shown in FIG. 2G). A spacer 222 is then formed on the sidewalls of the poly silicon gate 206 to surround the poly silicon gate 206 and cover a portion of the first LDD region 224a and the second LDD region 224b (as shown in FIG. 2H). Subsequently, the uncovered portions of the first LDD region 224a and the second LDD region 224b are subjected to an ion implantation process or a plasma doping process to form the source 218 and the drain 220 (as shown in FIG. 2I).

It should be appreciated that the aforementioned A LDD implantation process is optional. In other words, in some other embodiments, the source 218 and the drain 220 can be formed on the two opposite sides of the silicon fin 204 adjacent to the poly silicon gate 206 by the ion implantation process (or the plasma doping process) directly conducted on the silicon fin 204.

In some embodiments of the present invention, a silicide layer 226 may be further formed on the poly silicon gate 206, the source 218 and the drain 220 (as shown in FIG. 2J).

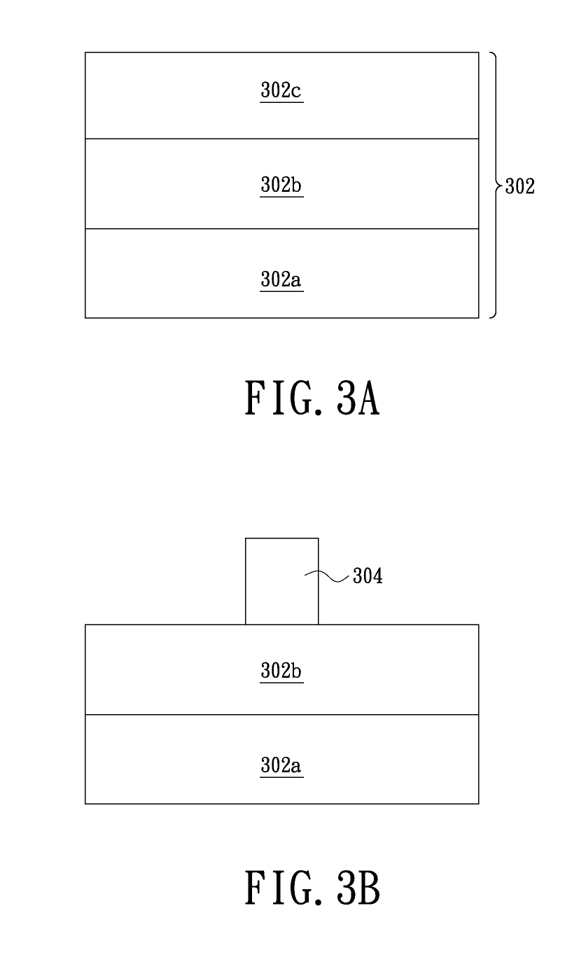

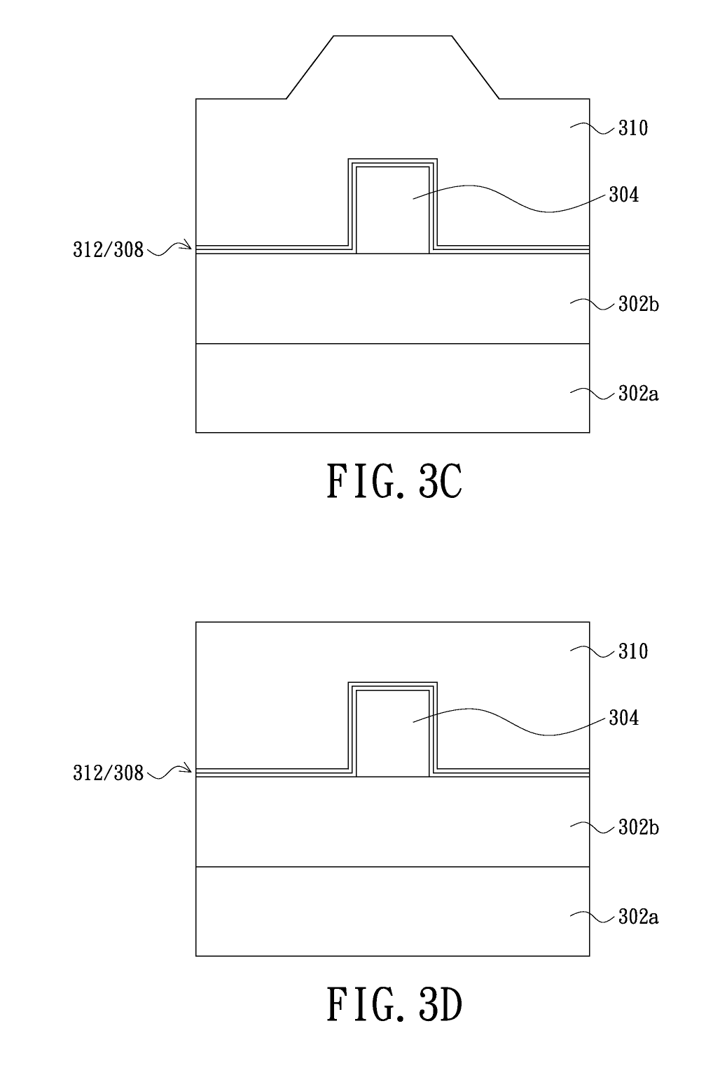

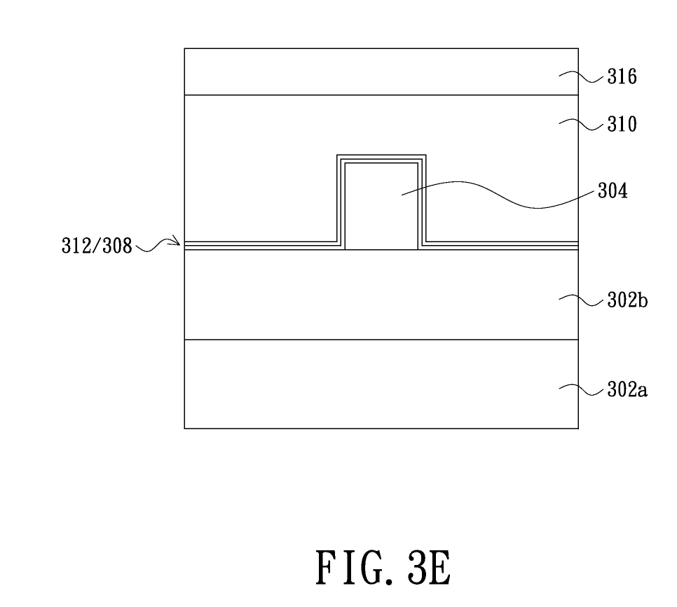

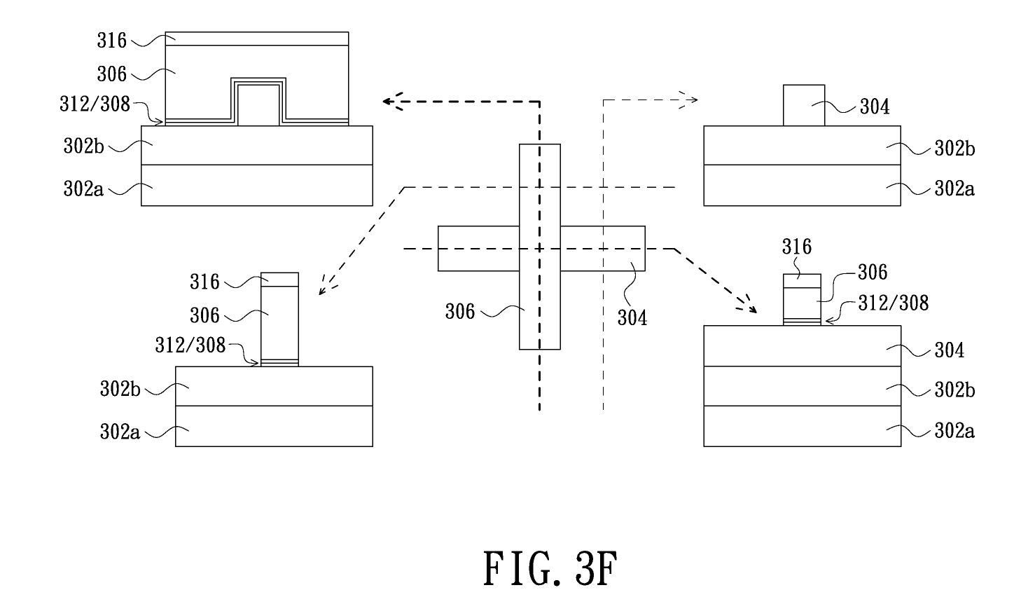

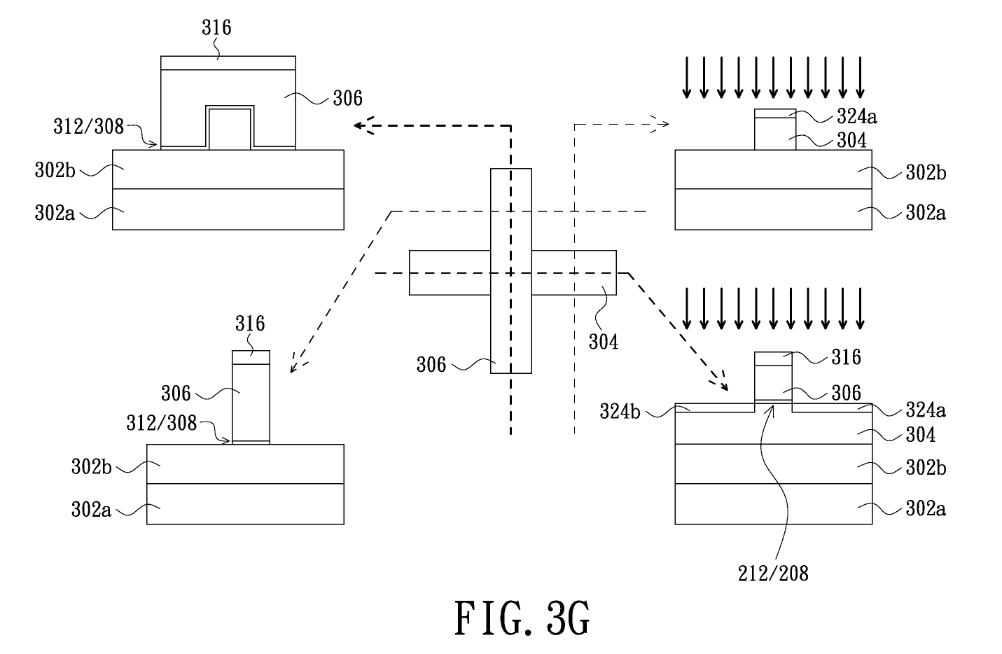

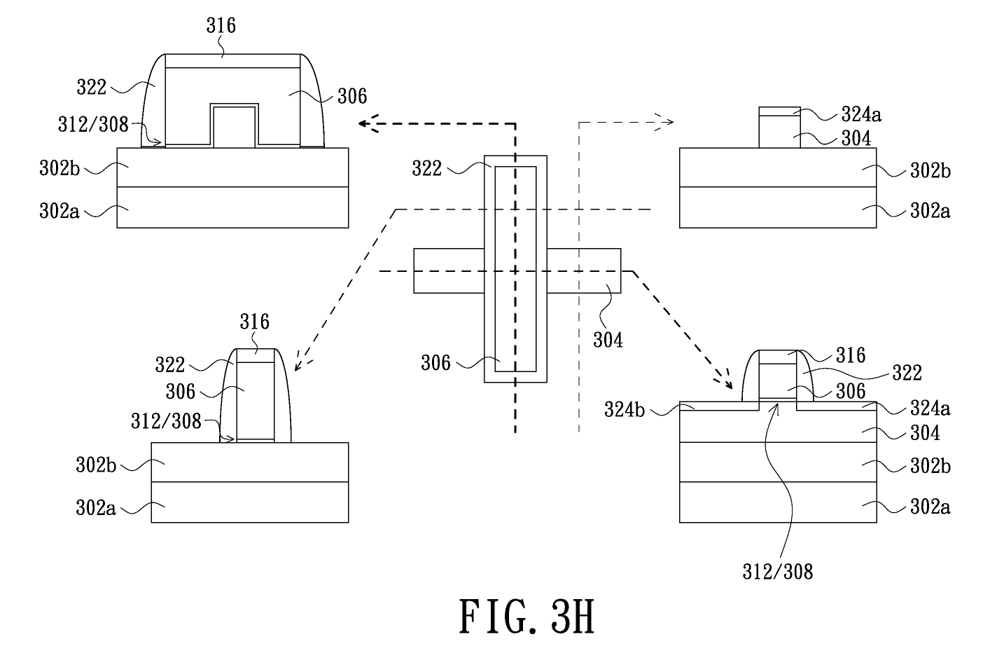

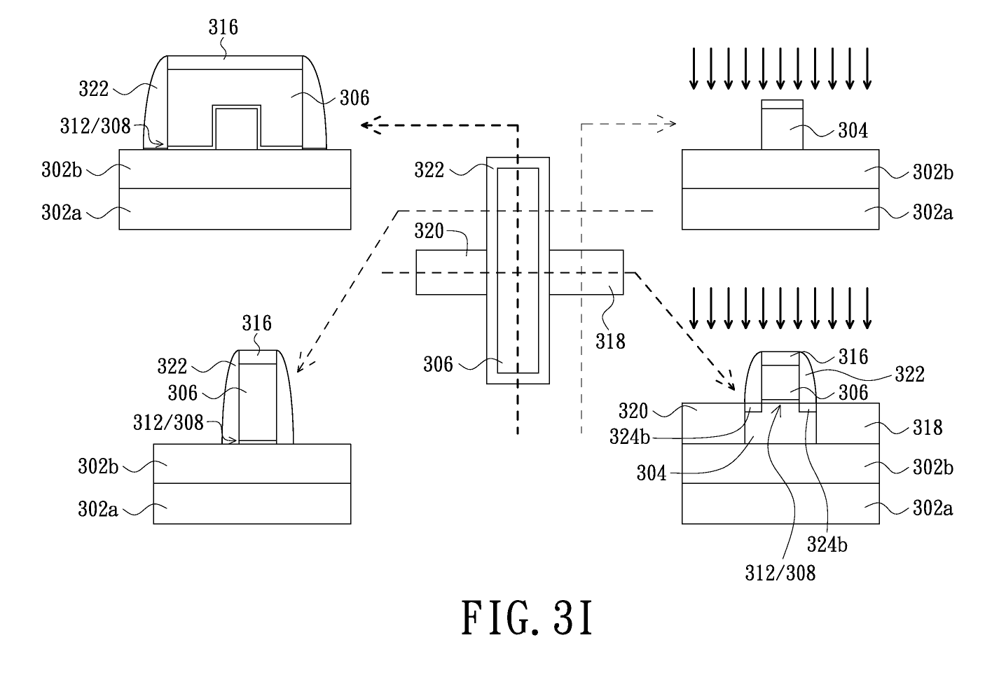

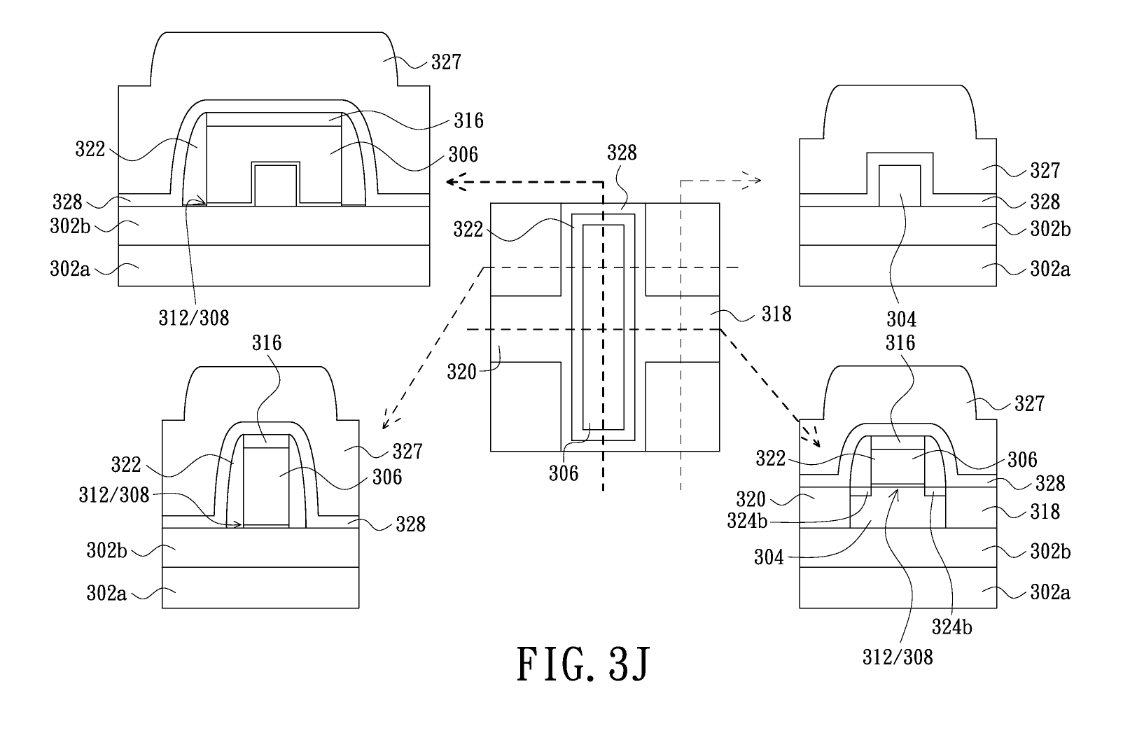

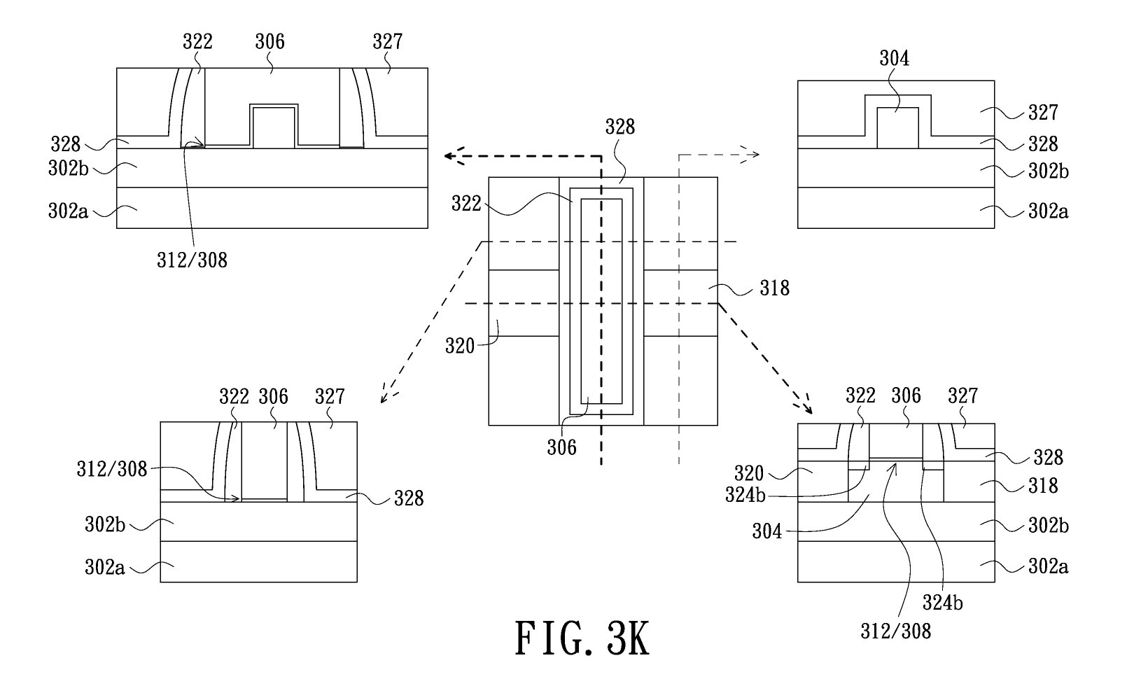

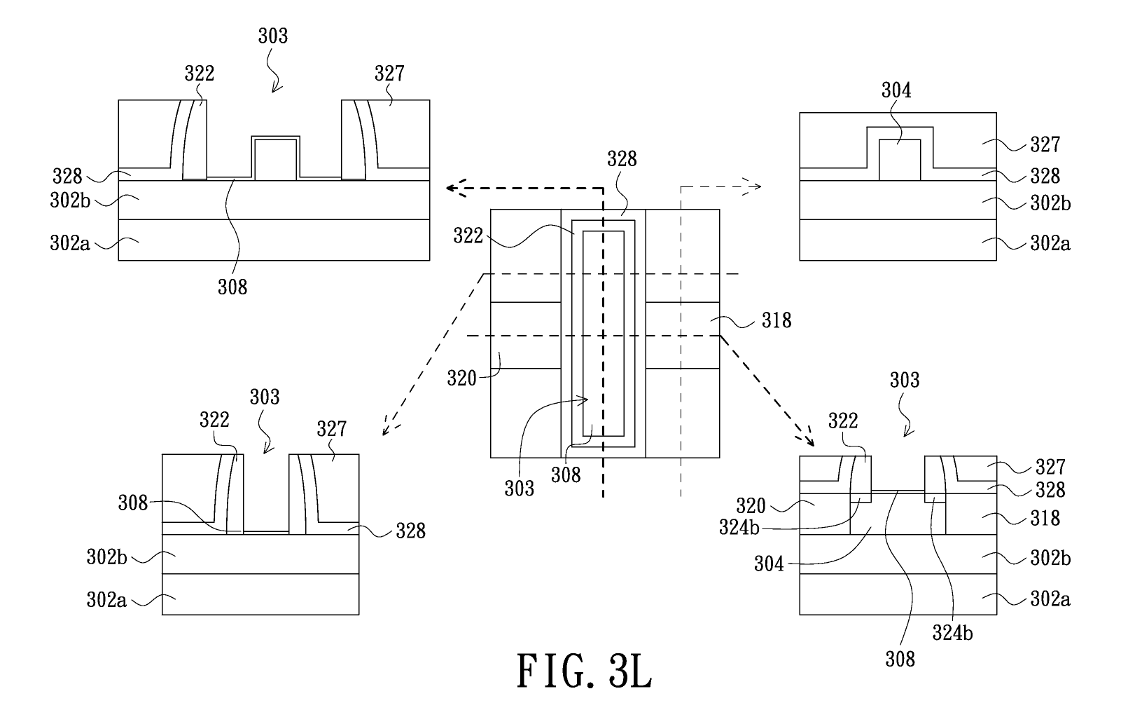

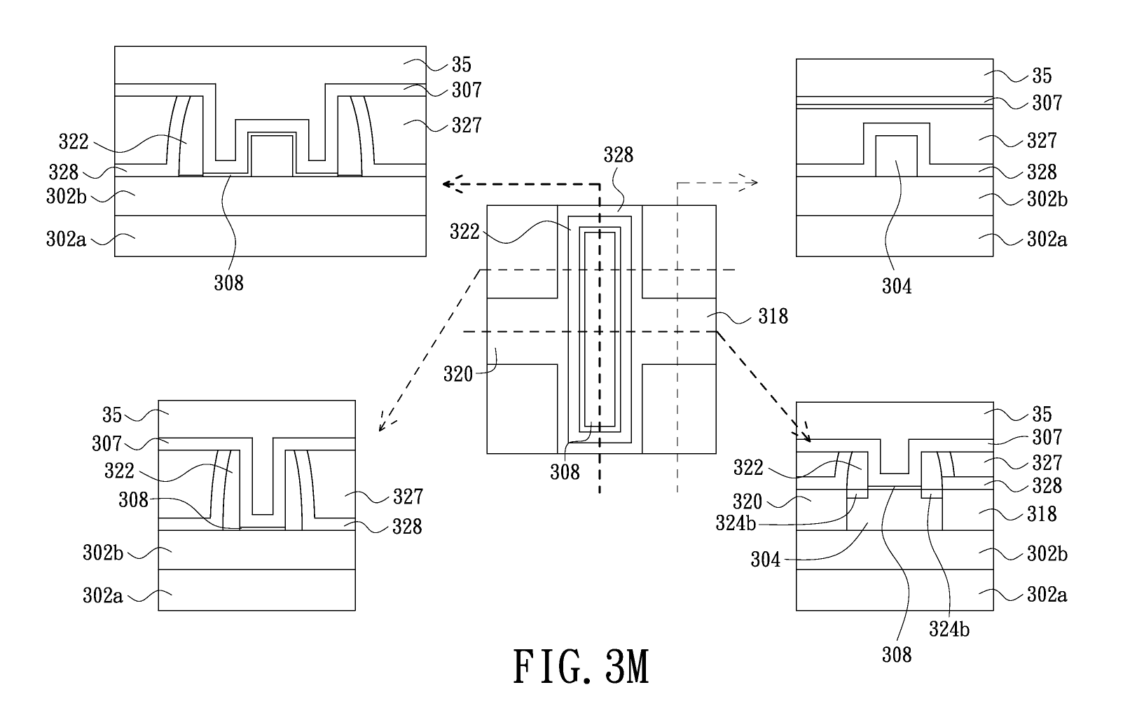

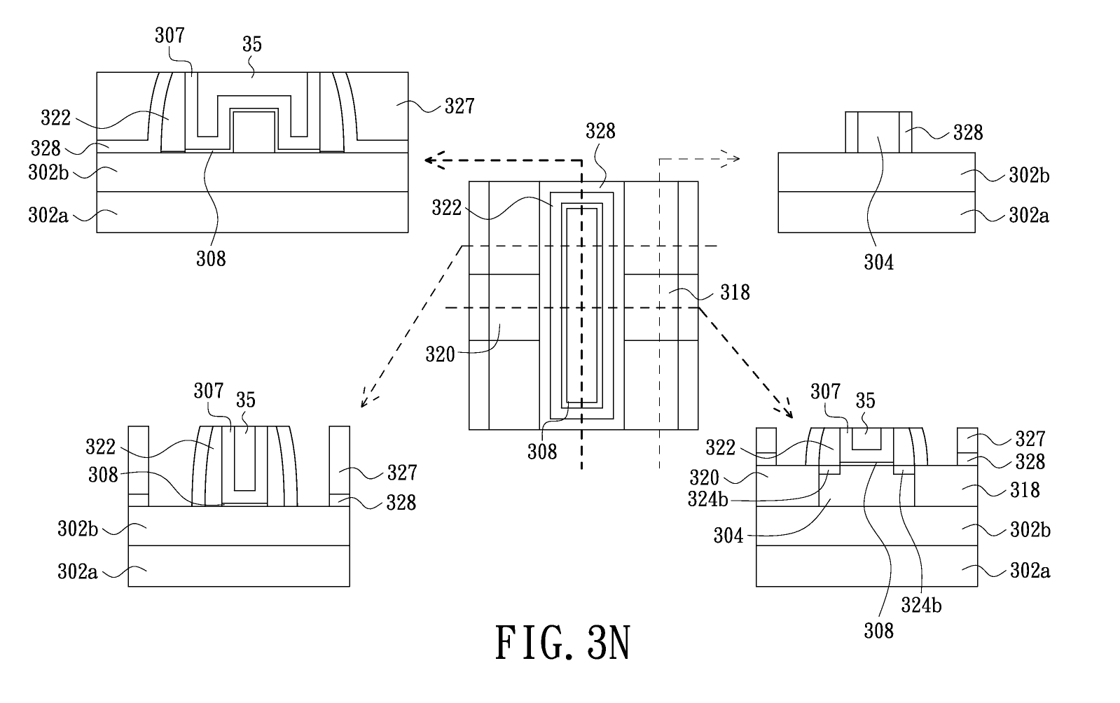

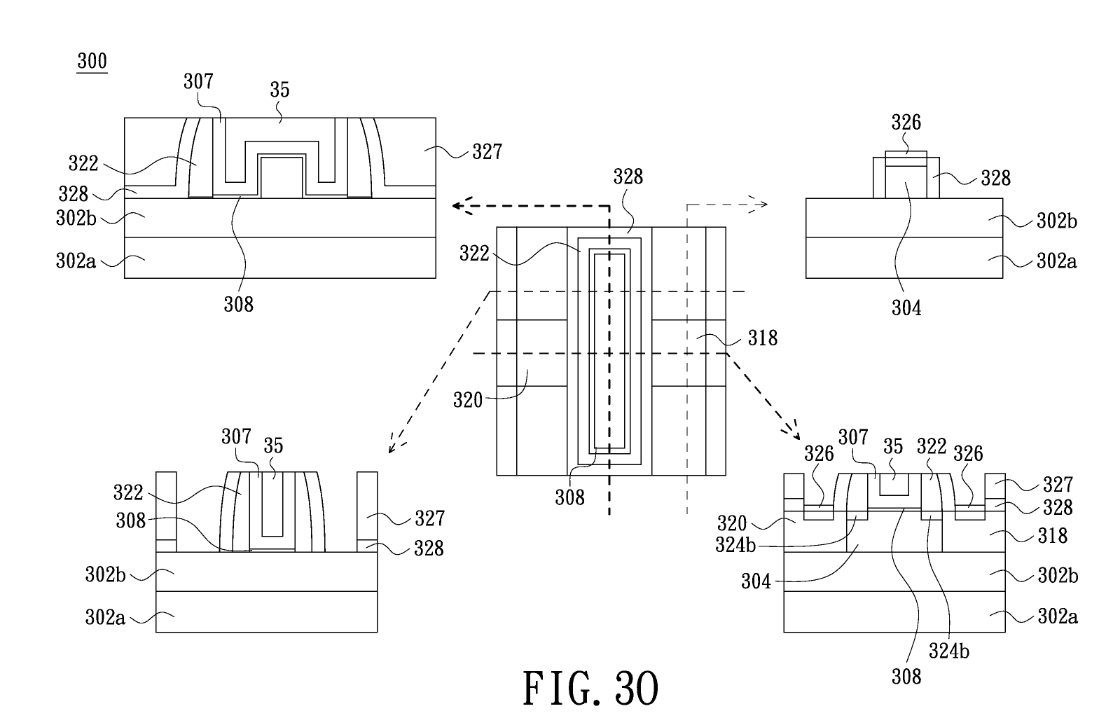

FIGS. 3A to 3O illustrate schematic diagrams of a process for fabricating a fin-FET 300 in accordance with further another embodiment of the present invention.

In the present embodiment the method for fabricating the fin-FET 300 comprises several steps as follows: A substrate 302 is first provided. As shown in FIG. 3A, the substrate 302 is a SOI substrate having a silicon base 302a, an insulator layer 302b and an epitaxial silicon layer 302c.

A silicon fin 304 is then formed in the SOI substrate 302. In the present embodiment, the silicon fin 304 is formed by a conventional lithography and etching process, whereby the epitaxial silicon layer 302c is patterned to form the three dimensional silicon fin 304 and a portion of the insulator layer 302b is exposed. The three dimensional silicon fin 304 is a bulk structure shapes as a rectangular solid, a cylinder or a polyhedron. In the preset embodiment, the three dimensional silicon fin 304 is a rectangular solid (as shown in FIG. 3B).

Next, a dielectric layer 308 is formed blanket over the silicon fin 304 and the exposed insulator layer 302b. Subsequently, a poly silicon layer 310 is formed further blanket over the dielectric layer 308. In some embodiments, a gate material layer 312 may be formed on dielectric layer 308, before the poly silicon layer 310 is formed on dielectric layer 308 (as shown in FIG. 3C).

Since the three dimensional silicon fin 304 is a rectangular solid protruding from the surface of the SOI 304, thus the SOI 304 has an undulating surface topography, and when the dielectric layer 308, the gate material layer 312 and the poly silicon layer 310 are blanketed onto the three dimensional silicon fin 304, the surface of the poly silicon layer 310 may undulates in comply with the undulating topography of the SOI 304, and the production yield may be inversely affected. To avoid this inverse effect, a planarization step, such as a CMP step, is conducted to remove a portion of the poly silicon layer 310 (as shown in FIG. 3D), so as to render the undulating topography of the poly silicon layer 310 more relief.

After the planarization step is implemented, the planarized poly silicon layer 310 is patterned to define a poly silicon gate 306 (as shown in FIG. 3F). In the present embodiment, the poly silicon gate 306 is defined by a conventional lithography and etching process. Before the poly silicon layer 310 is patterned, a hard mask consisted of silicon nitride or silicon oxide may preferably be formed on the planarized poly silicon layer 310 (as shown in FIG. 3E).

Since the undulating topography of the poly silicon layer 310 is relieved by the planarization step, the poly silicon gate 306 defined from the planarized poly silicon layer 310 has a flat roof. In other words, the top surface of poly silicon gate 306 do not undulated in accordance with the undulating topography of the SOI substrate 302, even if the poly silicon gate 306 straddles several three dimensional silicon fins 304.

After the poly silicon gate 306 is formed, a source 318 and a drain 320 are separately formed on two opposite sides of the silicon fin 304 adjacent to the ploy silicon gate 306. In the present embodiment, the formation of the source 318 and the drain 320 comprises the following steps: A LDD implantation process is first conducted to form a first LDD region 324a and a second LDD region 324b on the two opposite sides of the silicon fin 304 adjacent to the poly silicon gate 306, whereby the poly silicon gate 306 can straddle over the silicon fin 304 between the first LDD region 324a and the second LDD region 324b (as shown in FIG. 3G). A spacer 322 is then formed on the sidewalls of the poly silicon gate 306 to surround the poly silicon gate 306 and cover a portion of the first LDD region 324a and the second LDD region 324b (as shown in FIG. 3H). Subsequently, the uncovered portions of the first LDD region 324a and the second LDD region 324b are subjected to an ion implantation process or a plasma doping process to form the source 318 and the drain 320 (as shown in FIG. 3I).

It should be appreciated that the aforementioned A LDD implantation process is optional. In other words, in some other embodiments, the source 318 and the drain 320 can be formed on the two opposite sides of the silicon fin 304 adjacent to the poly silicon gate 306 by the ion implantation process (or the plasma doping process) directly conducted on the silicon fin 304.

In the present embodiment, after the source 318 and the drain 320 are formed, the method for fabricating the fin-FET 300 further comprises steps of removing the poly silicon gate 306 and subsequently forming a metal gate 305.

The process of removing the poly silicon gate 306 comprises steps as follows: A contact etch stop layer (CESL) 328 and an internal dielectric layer 327 are formed on the ploy silicon gate 306 and the SOI substrate 302 in sequence to blanket the ploy silicon gate 306, the source 318, the drain 320 and the exposed insulator layer 302b (as shown in FIG. 3J). Next, a planarization process is then conducted on the internal dielectric layer 327 to expose the poly silicon gate 306 (as shown in FIG. 3K). Subsequently, the poly silicon gate 306 and the gate material layer 312 are removed, so as to form an opening 303 in the remained internal dielectric layer 327, whereby a portion of the dielectric layer 308 is exposed (as shown in FIG. 3L). In other embodiments of the present invention, the dielectric layer 308 may be also removed with the poly silicon layer 306, whereby the undoped portion of the silicon fin 304 can be exposed.

In some embodiments of the present invention, the formation of the metal gate 305 comprises steps as follows: A metal layer 35 is formed on the internal dielectric layer 327 to fulfill the opening 303 (as shown in FIG. 3M). A polishing process is then conducted on the metal layer 35 and stopped on the internal dielectric layer 327 to remove a portion of the metal layer 35 and a portion of the internal dielectric layer 327, so as to form the metal gate 305 (as shown in FIG. 3N). Subsequently, a silicide layer 326 is formed on the source 318 and the drain 320.

According to aforementioned embodiments of the present invention, a method for fabricating a fin-FET is provided, wherein the source and the drain of the fin-FET are separately formed on a three dimensional fin, and the gate straddles on the fin between the source and drain. By way of conducting a planarization step on a poly silicon layer that is used to form a gate structure during the process for fabricating the fin-FET, the undulating topography of the gate structure can be made more even in order to comply with the process requirement of new generation semiconductor, whereby the production yield can be increased.

The present invention has been disclosed above in the preferred embodiments, but is not limited to those. It is known to persons skilled in the art that some modifications and innovations may be made without departing from the spirit and scope of the present invention. Therefore, the scope of the present invention should be defined by the following claims.

What is claimed is:

1. A method for fabricating a fin field effect transistor (fin-FET), the method comprising:
providing a substrate;
forming a silicon fin in the substrate;
forming a dielectric layer on the silicon fin and the substrate;
forming a poly silicon layer on the dielectric layer;
planarizing the poly silicon layer;
patterning the planarized poly silicon layer to form a poly silicon gate and expose a portion of the silicon fin; and
forming a source and a drain separately on two opposite sides of the exposed silicon fin adjacent to the poly silicon gate.

2. The method of claim 1 for fabricating the fin-FET, wherein the substrate is a Silicon-on-Insulator (SOI) substrate.

3. The method of claim 2 for fabricating the fin-FET, wherein the SOI substrate comprises a silicon base, an insulator layer and an epitaxial silicon layer.

4. The method of claim 3 for fabricating the fin-FET, wherein the formation of the silicon fin comprises a step of patterning the epitaxial silicon layer to form a three dimensional silicon fin and expose a portion of the insulator layer.

5. The method of claim 1 for fabricating the fin-FET, wherein the dielectric layer comprises a high dielectric constant layer.

6. The method of claim 1 for fabricating the fin-FET, further comprising a step of forming a gate material layer on the dielectric layer before the poly silicon layer is formed on the dielectric layer.

7. The method of claim 6 for fabricating the fin-FET, wherein the formation of the source and the drain comprises steps as follows:
conducting an optional light doped drain (LDD) implantation process to form a first LDD region and a second LDD region on two opposite sides of the silicon fin adjacent to the poly silicon gate;
forming a spacer on the sidewalls of the poly silicon gate to surround the poly silicon gate; and
conducting an ion implantation process or a plasma doping process on the first LDD region and the second LDD region.

8. The method of claim 6 for fabricating the fin-FET, further comprising forming a silicide layer on the poly silicon gate, the source and the drain.

9. The method of claim 6 for fabricating the fin-FET, further comprising removing the poly silicon gate, and forming a metal gate after the source and drain are defined.

10. The method of claim 9 for fabricating the fin-FET, wherein the step of removing the poly silicon gate comprises steps as follows:
forming an internal dielectric layer on the ploy silicon gate and the substrate;
conducting a planarization process on the internal dielectric layer to expose the poly silicon gate; and
removing the poly silicon gate and the gate material layer to form an opening in the internal dielectric layer, whereby a portion of the dielectric layer can be exposed from the opening.

11. The method of claim 10 for fabricating the fin-FET, further comprising forming a contact etch stop layer (CESL) on the ploy silicon gate and the SOI before the internal dielectric layer is formed on the ploy silicon gate and the SOI.

12. The method of claim 10 for fabricating the fin-FET, wherein the formation of the metal gate comprises steps as follows:
forming a metal layer on the internal dielectric layer to fulfill the opening; and
conducting a polishing process on the metal layer stopped on the internal dielectric layer to remove a portion of the metal layer and a portion of the internal dielectric layer.

13. The method of claim 9 for fabricating the fin-FET, wherein the step of removing the poly silicon gate comprises removing the poly silicon gate, the gate material layer and the dielectric layer to form an opening in the internal dielectric layer, whereby a portion of the silicon fin can be exposed from the opening.

14. The method of claim 1 for fabricating the fin-FET, wherein the planarization of the poly silicon layer comprises chemical mechanical polishing (CMP).

15. The method of claim 1 for fabricating the fin-FET, further comprising forming an advanced patterning film (APF) on the poly silicon layer before the poly silicon layer is planarized.

16. The method of claim 1 for fabricating the fin-FET, further comprising forming a hard mask on the planarized poly silicon layer before the planarized poly silicon layer is patterned.

17. The method of claim 15 for fabricating the fin-FET, wherein the hard mask is made of silicon nitride or silicon oxide.
